(19) United States
(12) Patent Application Publication
(10) Pub. No.: US 2015/0091588 A1
(43) Pub. Date: Apr. 2, 2015

(54) COMPACT AND DURABLE BUTTON WITH BIOMETRIC SENSOR HAVING IMPROVED SENSOR SIGNAL PRODUCTION AND METHOD FOR MAKING SAME

(71) Applicant: SYNAPTICS INCORPORATED, San Jose, CA (US)

(72) Inventors: Paul WICKBOLDT, Walnut Creek, CA (US); Eric JONES, Santa Cruz, CA (US); Young Seen LEE, Newark, CA (US); Steven MOLESA, San Jose, CA (US); Jeff KELSOE, Palm Desert, CA (US)

(21) Appl. No.: 14/500,771

(22) Filed: Sep. 29, 2014

Related U.S. Application Data
(60) Provisional application No. 61/885,260, filed on Oct. 1, 2013.

(51) Int. Cl. G01R 27/26

(52) U.S. Cl. CPC G01R 27/2605
USPC 324/661

(57) ABSTRACT

A biometric sensor and button assembly and method of making same are disclosed which may comprise: a button housing comprising at least two side walls each forming a vertical load absorbing tower and defining an opening within the button housing; an insert within the opening within the housing; a sensor controller integrated circuit positioned within a cavity formed in one of the insert, the housing or a combination of the insert and the housing; and the insert and the housing cooperating to absorb vertical loading on the button housing, thereby protecting the integrated circuit from excess vertical loading. The assembly and method may also comprise the biometric comprising a fingerprint sensed by the biometric sensor. The assembly and method may also comprise the at least two side walls comprising at least four side walls, the cavity being formed within the bottom of the insert, within the housing, or both.

### CROSS-REFERENCE

This application claims the benefit of U.S. Provisional Application No. 61/885,260, filed Oct. 1, 2013, which application is incorporated herein by reference.

### BACKGROUND

Compact button designs including biometric sensor, e.g., fingerprint sensor, elements integrated with the button assembly have been designed. However, certain aspects of such designs, while satisfying the need for compactness and integration of the sensor elements and, perhaps also, a sensor controller integrated circuit, have been not fully satisfactory. As an example, the button design, strength and/or construction may not sufficiently protect the IC, or one or more of the layers covering the sensor elements, e.g., from applied forces, such as, vertically applied force. In such prior buttons the controller IC was attached to the underside of a flex sensor element and IC mounting substrate, e.g., directly under the sensor element area or also under the entire button structure itself. While such arrangements can provide the advantage of having an extremely compact COF button and sensor arrangement, and thus, e.g., facilitate very low cost high volume manufacturing. Nevertheless, the IC has been found to be susceptible to damage or even destruction by the placement by a user of the finger of the user on the button over the sensor element area, e.g., a finger swiping or placement area. Even more so, however, damage to the IC can occur, as an example, where the consumer device in which the button is mounted and utilized, e.g., is dropped and the stress of an applied vertical force to the button assembly serving to damage or destroy the IC or its relatively rigid silicon wafer substrate, with the applied vertical force.

According to aspects of the disclosed subject matter such shortcomings have been eliminated or at least alleviated.

### SUMMARY

An aspect of the disclosure is directed to sensor and button apparatuses. Suitable sensor and button apparatuses, comprise: a flexible substrate; sensor elements disposed on the flexible substrate; an integrated circuit (IC) disposed on the flexible substrate, the IC being communicatively coupled to the sensor elements; an insert having a top side and a bottom side; and a button housing having a top side, a bottom side, and at least one sidewall, wherein the flexible substrate is wrapped around the insert with the sensor elements of the flexible substrate at the top side of the insert, and wherein the insert is disposed within an interior of the button housing with the top side of the insert corresponding to the top side of the button housing. Additionally, the flexible substrate can be wrapped around the insert includes a portion extending outside of the button housing, and the IC is disposed on the portion of the flexible substrate extending outside of the button housing. In some configurations, the at least one sidewall includes a slot, and wherein the portion of the flexible substrate extending outside of the button housing extends from the insert through the slot. The flexible substrate can also be wrapped around the insert with the IC at the bottom side of the insert. The insert is configurable to include a cavity, and wherein the IC is disposed within the cavity of the insert. Further, the IC can be disposed facing up from the flexible substrate within the cavity of the insert. Additionally, the button housing can define a cavity, and wherein the IC is disposed within the cavity of the button housing. In some configurations, the IC is disposed facing down from the flexible substrate within the cavity of the button housing. The insert can also be configured to include a first cavity, wherein the button housing defines a second cavity, and wherein the IC is disposed within the first cavity of the insert and the second cavity of the button housing. In some configurations, the at least one side wall is configurable to include at least one ledge in the interior of the button housing, and wherein the insert with the flexible substrate wrapped around it is vertically supported by the ledge. Additional configuration can further comprise: a hard top film, wherein the sensor elements are disposed facing up from the flexible substrate at the top side of the insert, and wherein the hard top film coats the flexible substrate at the top side of the insert. Some configurations also comprise: a conformal coating, wherein the sensor elements are disposed facing down from the flexible substrate at the top side of the insert, and wherein the conformal coating coats the flexible substrate at the top side of the insert. Sensor elements can also comprise a capacitive sensor array, a swipe fingerprint sensor array, and/or a placement fingerprint sensor array. Capacitive sensor arrays can include, such as a capacitive fingerprint sensor array. Additionally, the button housing is configurable to provide a user depressible from the top side of the button housing. Additional configurations can include a device housing, wherein the button housing is disposed in the device housing and user depressible relative to the device housing.

Another aspect of the disclosure is directed to sensor and button apparatuses. Suitable sensor and button apparatuses comprise: a flexible substrate; fingerprint sensor electrodes disposed on the flexible substrate; an integrated circuit (IC) disposed on the flexible substrate, the IC being communicatively coupled to the sensor electrodes; an insert having a top side and a bottom side; and a button housing having a top side, a bottom side, and at least one sidewall, the button housing being user depressible from the top side of the button housing, wherein the flexible substrate is wrapped around the insert with the sensor electrodes of the flexible substrate at the top side of the insert and the IC at the bottom side of the insert, wherein the insert is disposed within an interior of the button housing with the top side of the insert corresponding to the top side of the button housing, wherein the insert comprises a cavity at the bottom side of the insert, wherein the IC is disposed facing up from the flexible substrate within the cavity of the insert.

Still another aspect of the disclosure is directed to sensor and button apparatuses, comprising: a flexible substrate; fingerprint sensor electrodes disposed on the flexible substrate; an integrated circuit (IC) disposed on the flexible substrate, the IC being communicatively coupled to the sensor electrodes; an insert having a top side and a bottom side; and a button housing having a top side, a bottom side, and at least one sidewall, the button housing being user depressible from the top side of the button housing, wherein the flexible substrate is wrapped around the insert with the sensor electrodes of the flexible substrate at the top side of the insert and the IC at the bottom side of the insert, wherein the insert is disposed within an interior of the button housing with the top side of the insert corresponding to the top side of the button housing, wherein the button housing defines a cavity at the bottom side of the button housing, wherein the IC is disposed within the cavity of the button housing facing down from the flexible substrate and facing down from the insert.

It will be understood that a biometric sensor and button combination assembly and method of making same is disclosed which may comprise: a button housing comprising at least two side walls each forming a vertical load absorbing tower and defining an opening within the button housing; an insert within the opening within the housing; a sensor controller integrated circuit positioned within a cavity formed in one of the insert, the housing or a combination of the insert and the housing; and the insert and the housing cooperating to absorb vertical loading on the button housing, thereby protecting the integrated circuit from excess vertical loading. The assembly and method may also comprise the biometric comprising a fingerprint sensed by the biometric sensor when a finger of a user presses on the top of the button to invoke the functionality of the button. The assembly and method may also comprise the at least two side walls comprising at least four side walls, the cavity being formed within the bottom of the insert, spaced from the top of the button, or within the housing under the bottom of the insert, or both.

The assembly and method may further comprise the housing supporting the insert to prevent movement of the insert in a direction that would apply vertical loading applied to the button to the integrated circuit. The assembly and method may further comprise the insert being sized and constructed of material that prevents the insert from significantly bending in a direction that would apply to the integrated circuit any damaging amount of a vertical loading applied to the button. The assembly and method may further comprise the integrated circuit being mounted on a flexible substrate having sensor element traces formed on one surface of the substrate facing a top of the button on a top side of the insert and facing a bottom of the button on a bottom side of the insert or formed on one surface of the substrate facing a bottom of the button on a top side of the insert and facing a top of the button on a bottom side of the insert.

The assembly and method may further comprise the assembly being incorporated into a user authentication apparatus providing user authentication for controlling access to one of an electronic user device or an electronically provided service and the electronic user device comprises at least one of a portable phone, a computing device or the provided service comprises at least one of providing access to a web site or to an email account or controlling an online transaction or providing user authentication for controlling access to a physical location or demonstrating the user was present at a certain place at a certain time or for providing at least one of a finger motion user input or navigation input to a computing device or the performance by the user device of at least one other task specific to the particular finger of the user.

The assembly and method may further comprise a button housing comprising at least two side walls each forming a vertical load absorbing tower and defining an opening within the button housing; an insert within the opening within the housing; a flexible circuit substrate containing sensor element conductor traces formed over the insert, the insert and the vertical load absorbing towers cooperating to also absorb vertical loading on the button housing, thereby protecting the sensor conductor traces from damage due to excess vertical loading; and the flexible circuit substrate extending outside of the housing an having an integrated circuit mounted to the flexible circuit substrate outside of the housing of the button.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 illustrates a top plan view of a compact and durable button with a biometric sensor having improved sensor signal production according to aspects of embodiments of the disclosed subject matter;

FIG. 2 illustrates a top perspective view of the button of FIG. 1;

FIG. 3 illustrates a bottom perspective view of the button of FIGS. 1 and 2;

FIG. 4 illustrates a left side view of the button of FIGS. 1-3;

FIG. 5 illustrates an exploded view of the button of FIGS. 1-4;

FIG. 6 illustrates a first lateral cross-sectional view of the button of FIGS. 1-5;

FIG. 7 illustrates a second lateral cross-sectional view of the button of FIGS. 1-6;

FIG. 8 illustrates a longitudinal cross-sectional view of the button of FIGS. 1-7;

FIG. 9 illustrates a top perspective view of another compact and durable button with a biometric sensor having improved sensor signal production according to aspects of embodiments of the disclosed subject matter;

FIG. 10 illustrates a bottom perspective view of the button of FIG. 9;

FIG. 11 illustrates a lateral cross-sectional view of the button of FIGS. 9 and 10;

FIG. 12 illustrates a longitudinal cross-sectional view of the button of FIGS. 9-11;

FIG. 13 illustrates a lateral cross-sectional view of another compact and durable button with a biometric sensor having improved sensor signal production according to aspects of embodiments of the disclosed subject matter; and

FIG. 14 illustrates schematically, another possible sensor/button assembly, according to aspects of embodiments of the disclosed subject matter.

### DETAILED DESCRIPTION

According to aspects of the disclosed subject matter, a compact button and biometric sensor assembly can be provided whereby the tendencies of the prior designs to have the sensor control integrated circuit (IC), e.g., housed in the button structure, not be sufficiently robust, e.g., in the face of the above noted vertical loading or repeated instances of such loading. It will be understood that as used in the present application such denominatives as horizontal or vertical or the like, or top, bottom and side, or the like are utilized for illustrative discussion only and to help understand the orientation and functionality of various components of the disclosed subject matter, and also, generally to align only with the view shown in a given figure, e.g., as aligned in the plane of the paper. These are not intended to limit the actual positioning of the structures so described in any real world coordinate system, where, of course, the “top” or “bottom” may be otherwise aligned with the real world coordinate system, etc.

According to aspects of the disclosed subject matter, the combination button and biometric sensor arrangement is intended to be at least as compact as prior arrangements, i.e., generally meaning less thick in the vertical direction, from top to bottom, but also more durable, especially with respect to the durability of the controller IC. Also, according to aspects of the disclosed subject matter the button/sensor assembly can be such that the IC does not bear direct impact of vertical loading, e.g., from the user device being dropped or from impact tests, simulating the same, or the like, while still maintaining as minimum a form factor of the overall button itself as can be (particularly vertically). This can be accomplished in a myriad of different ways as articulated below, and can depend in part on specific materials and structures employed. In addition to the improved durability, according to aspects of embodiments of the disclosed subject matter, improved cosmetics can also be achieved and ease and diversity of manufacturing techniques and methods and materials usage can be promoted.

In addition two general button/sensor assemblies can be implemented with aspects of the disclosed subject matter. A first may, e.g., have the controller IC removed from even the possibility of direct loading. Such a construction could apply to both sensors employing one dimensional (1D) or two dimensional (2D) arrays of sensors, i.e., formed on a flexible sensor element substrate, which is within the button itself. In such an arrangement, the sensor controller IC can be outside of the structure of the button, per se. As explained in more detail below, the sensor element part of the flex substrate, passing under the sensing area, e.g., on the top surface of the button, can then be routed, along with the sensor IC mounted thereon, e.g., a chip on flex (COF) mounting, out of the front, back, or side of the button. In this manner only the button housing itself and the sensor part of the flex are exposed to direct vertical loading and impacts. The flex substrate with the sensor elements formed on the flex substrate, e.g., by an etched metal layer applied to the flex substrate, has proven very durable to such loading, particularly with a protective layer(s) over the sensor elements themselves on the flex substrate or other protective layers of the button assembly, or both, also providing for greater durability under such loading.

Such a design, discussed in more detail below, e.g., with respect to FIG. 13 has been found to enable the formation of very thin button/biometric sensor arrangements, e.g., ranging from 0.2 to 1.2 mm in height. Maintained is the button functionality, i.e., such that the button housing can be depressed, e.g., within an opening in a housing of a user device containing the remainder of the button operating mechanism, such as a physical switch mechanism operated by depressing, or otherwise manipulating or moving the button housing to operate as a button. Also maintained is, e.g., the rigidity of the button. An insert may be used as discussed in more detail in the present application, e.g., to increase the rigidity of the button, especially in the vertical direction. A stiffener, e.g., under the entire button/sensor assembly itself, may also be used for more support, as discussed below. Such a design is illustrated in connection with FIG. 13.

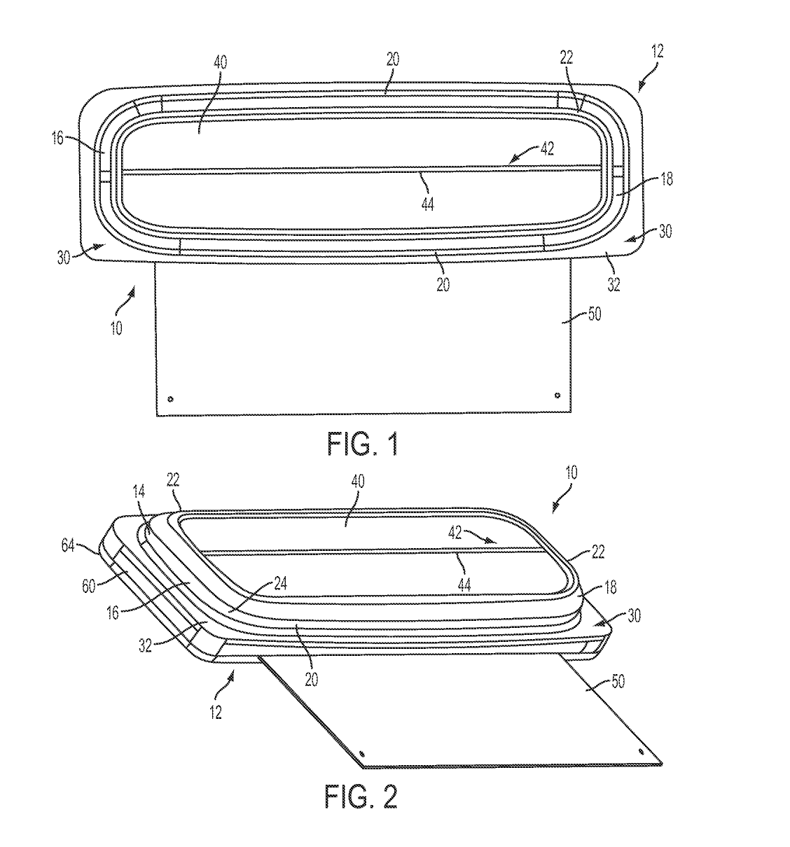

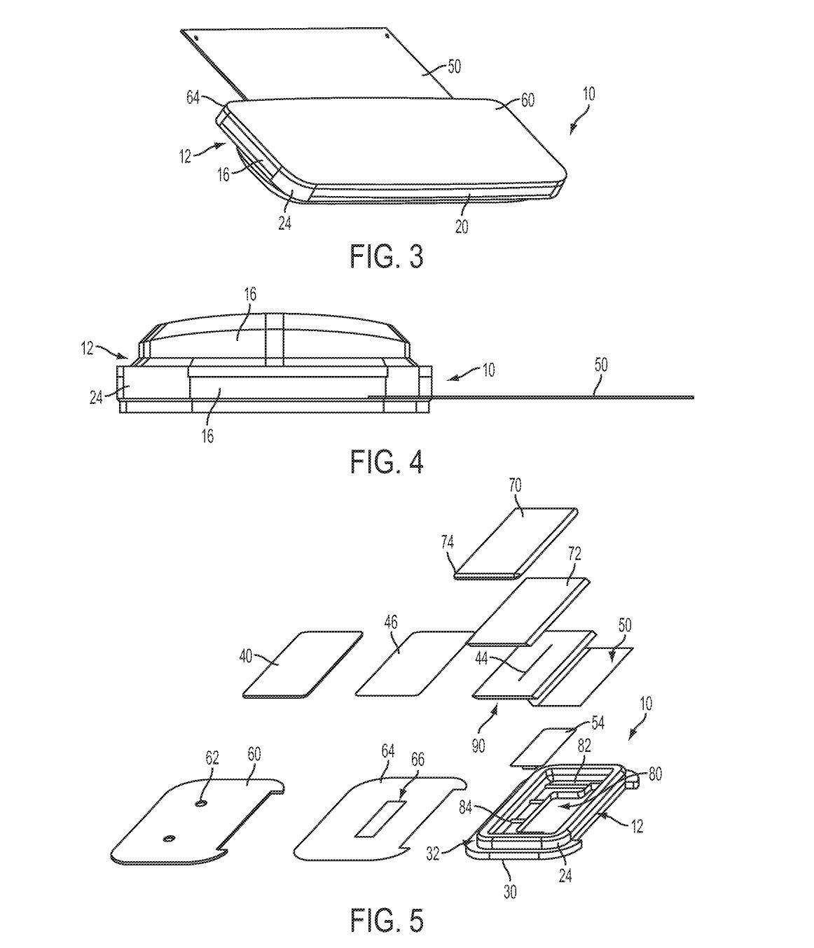

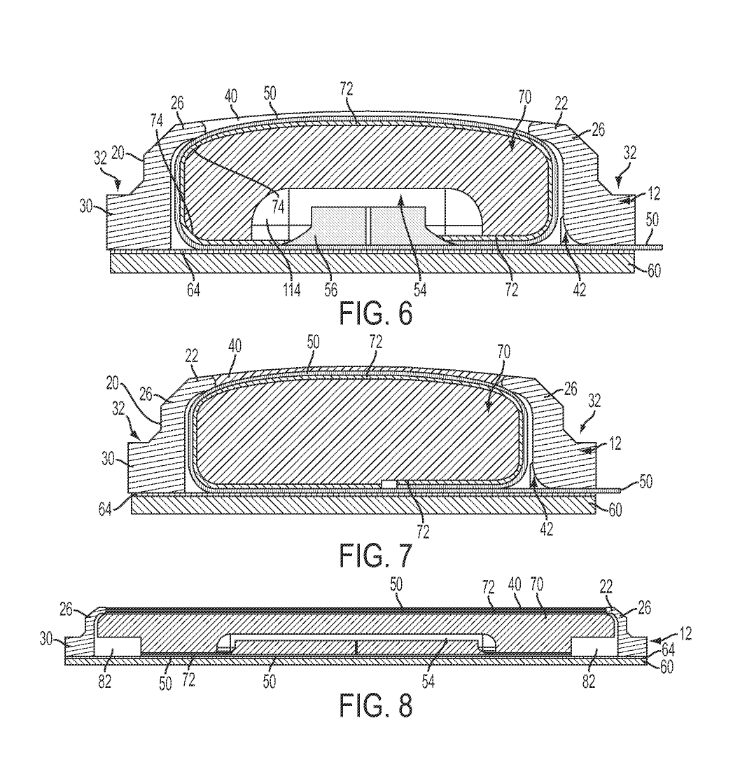

A second possible design can serve, e.g., to remove the controller IC from direct vertical loading, or at least significantly decrease such loading, and according to aspects of the disclosed subject matter can have the controller IC within a cavity in the button/sensor assembly. In such case, a vertically extending side wall of the button, surrounding the cavity, can form vertical support tower, e.g., to absorb the vertical loading. In addition, as another example, an insert can be placed in between the controller IC and the top surface of the button where the sensor part of the flex substrate resides, with internal support to maintain the insert in a position to strengthen the overall button assembly, support the sensor element flexible substrate in the sensor element sensing area, but not place loading on the controller IC itself, particularly vertical loading. In such a design the controller IC can reside inside the button/sensor assembly, giving the overall design a more compact footprint while maintaining compact thickness. Such arrangements are discussed in more detail with respect to FIGS. 1-12 and 14.

The strength and hardness of the insert are important considerations, which may also lead to choice of dimensions (e.g., width vs. thickness) and the choice of materials (polycarbonate, nylon, glass filled, metal with insulated coating, etc.) is to be considered. As will be discussed in more detail below, also, the size, shape and supporting structures and encapsulating materials, and the like, for a cavity to house the controller IC itself have a significant role to play in the design. The cavity may be where the controller application-specific integrated circuit (ASIC) will fit into the insert itself, or the insert may form the cavity with the rest of the button housing structure, e.g., with the insert above the cavity and vertically supported by the button housing structure, or both, as illustrated schematically in FIG. 14. The cavity can be made with or without potting material also supporting the controller IC.

In order to minimize overall button vertical profile having as thin a vertical profile as possible, e.g., the IC silicon die itself and a COF mounting along with minimum encapsulation, etc. may be utilized. Additionally, the length/width of the cavity can be selected to fit the dimensions of the controller IC, and encapsulation, e.g., under fill. Also, the provision of as large a gap between the bottom of the controller IC and a stiffener, e.g., a metal plate, on the bottom of the button/sensor assembly can provide for more protection to the controller IC, but may need also to be adjusted so as not to create too thick of a button. A potting material may be added to the cavity as well to add more protection to the silicon die of the controller IC. The stiffener or bottom support of the whole button, itself, is a concern, needing to be thick enough to add strength against bending, but thin enough to also serve to minimize button height/thickness.

Those skilled in the art will understand that, for all of these factors there is always a trade-off(s) that must be made, e.g., between strength and size, with the size usually being paramount in order to make the button smaller vertically (thinner) and more compact, however, without also resulting in critical areas (e.g., insert, stiffener, and cavity) not being sized or constructed or supported such that the durability requirements are not passed. Those skilled in the art will understand that given the myriad of materials available and the possible constructions available, as illustrated in part in the present application, such dimensions and/or materials for maximizing the protection of the controller IC from vertical loading while minimizing button thickness can be readily selected without undue experimentation, especially given the guidance of the present disclosure.

External construction and cosmetics of the button/sensor arrangement are also important considerations. A top view shape of a button/sensor assembly according to aspects of the disclosed subject matter may be, e.g., made into a rectangle, a circle, an ellipse, or a combination, e.g., a pill shape. In the case of the rectangle where the edges of the button are straight with no radii the flex can be cut with straight edges and simply wrapped around a mandrel forming the insert within a cavity in the button/sensor arrangement. As an example, the edges of the flex can then sit flush with the edges of the button or a bezel can be added as well to cover the edges, as discussed in more detail below. In this type of button/sensor arrangement the sensor surface of the flex substrate (i.e., where the sensor element are formed on the flexible substrate) can be made flat or rounded (i.e., protrude up, at least slightly) in a rather straight forward assembly arrangement.

For convenience, embodiments of the disclosed subject matter will be discussed in the present application as part of a generally rectangular footprint, without limiting the disclosed subject matter to such a shape(s). In the case of a pill shaped button or button with radii, e.g., at the ends of the “pill-shaped” structural footprint, the edges of the flex can either be cut to conform to the desired shape or they can be cut with straight edges and the surface beneath the flex, e.g., that of the insert, can be designed to the desired rounded shape.

If the edges of the flex are so cut with wings or dog ears (i.e., cut with radii) then an adhesive between the flex and the bottom surface, e.g., the insert, may be provided to keep them from flapping up. However, a bezel could also be used to cover the edges of the flex, and in such case an adhesive may not be required since the bezel may keep the edges down. Adding a bezel may limit the shape of the surface where the flex resides, whether there is adhesive or not. Adding a bezel may also create a situation where the sensor elements on the flex substrate sit slightly below the top surface (i.e., the top of the bezel).

Because of this the button/sensor assembly could have to be made wider to accommodate good swipe ergonomics. In order to avoid widening the button, however, a hump may be added to the sensor flexible substrate surface, whereby, as an example, the sensor element flex substrate surface can be raised above the bezel upper surface. However, e.g., there can be a trade-off between using a bezel that covers the edges of the flex, creating a hump that allows for good ergonomics, and allowing edges of the bezel to protrude above the hump to maintain a minimum bezel thickness.

With a button having rounded edges with straight cut flex sides, as an example, the edges can have a straight surface, e.g., an insert, beneath it, which also may continue out to edges of the button to give the button a rounded edge look. Where the flex ends there can be created a physical step that can be difficult to hide, e.g., in the top surface. A recess may be created in the insert that, e.g., the flex can sit in and thereby create a flush top surface. Such an assembly can also serve to allow for extended sides of the insert, e.g., that could be shaped into dome-like shapes, which may not be possible with flex over the top, since the flex may not wrap around a dome shape in a flat manner. If, however, the sensor were attached onto a thermoforming substrate this could then be possible. Such dome-like edges, e.g., in conjunction with a hump shaped sensor element flex substrate surface could then create both superior ergonomics and improved cosmetics.

A final top surface/coating for a compact button could be created using a hard film, e.g., PET, Teflon®, etc., or even an ink or other spray-on protective coating. However, the shape of the surface beneath the top flex substrate film (e.g., the flex or the insert) can serve to determine which type of top coating may be used. A top coating comprised of a hard thin (1-5 mil) film can be used with a flat or hump/cylindrical shaped sensor surface since the film may be wrapped around dome-shaped surfaces only with some difficulty. A thermoforming film should not have such a problem. Also, a hard top film may be more tolerant to surface flatness blemishes and “seams,” e.g., more able to hide surface imperfections, due to its mechanical rigidity. A top surface spray coating solution can be compatible with any type of surface shape, e.g., since it deposits a conformal coating. However, the spray coating preferably should be flat and not have any “seams” or blemishes that the coating must hide. Thus a design where the edges of the flex extend to the edges of the button may be preferred.

For either type of coating the metal sensor element traces pattern could face up or down. In the case of the hard top film it may be preferred to have the sensor elements, e.g., the metal traces on the flex substrate, face up, since the extra material of having the metal face down could degrade the sensor signal. That is, e.g., the traces will be further from the sensing surface of the button where the biometric, e.g., the finger of the user, is placed or swiped. In this case the hard film can hide the structure and roughness created by the pattern of the sensor element metal traces. A spray coating can have more difficulty hiding this pattern, and thus it may be preferred to have the metal traces face down and coat the smooth side of the flex substrate, given a satisfactory signal strength at the receiver trace(s). The signal should still be strong enough since the spray film is thin.

Additionally, the top surface may also include other protective coatings, e.g., inks, as desired, based on use. The top surface may also include an oxide or nitride coloration as desired, also based on use. A layer of oxide or nitride can be used to change the color of the button, e.g., with the color created being determined by the thickness of the layer of oxide or nitride coating. The addition of sensor signal boosting structure can improve received signal to noise ration or the like, e.g., by mixing in high dielectric constant materials to sensor packaging or coating materials, such as within the flexible circuit substrate or the oxide or nitride or ink or other protective coatings. The thickness of the oxide or nitride layer can also be decided based on color preference and/or total thickness of, e.g., the top layer of the button. TABLE I shows as an example, specific colors and associated thicknesses for SiO₂, and Table II shows the same for Si₃N₄.

TABLE I

| Thickness | Color |
|---|---|
| 0.05 μm | Tan |
| 0.07 μm | Brown |
| 0.10 μm | Dark violet to red-violet |
| 0.12 μm | Royal blue |
| 0.15 μm | Light blue to metallic blue |
| 0.17 μm | Metallic to yellow-green |
| 0.20 μm | Light gold or yellow |
| 0.22 μm | Gold |
| 0.25 μm | Orange to melon |
| 0.27 μm | Red-violet |
| 0.30 μm | Blue to violet-blue |
| 0.31 μm | Blue |
| 0.32 μm | Blue to blue-green |
| 0.34 μm | Light green |
| 0.35 μm | Green to yellow-green |
| 0.36 μm | Yellow-green |
| 0.37 μm | Green-yellow |
| 0.39 μm | Yellow |
| 0.41 μm | Light orange |
| 0..42 μm | Carnation pink |
| 0.44 μm | Violet-red |
| 0.46 μm | Red-violet |
| 0.47 μm | Violet |
| 0.48 μm | Violet-blue |
| 0.49 μm | Blue |
| 0.50 μm | Blue-green |
| 0.52 μm | Green (broad) |
| 0.54 μm | Yellow-green |
| 0.56 μm | Green-yellow |
| 0.57 μm | Yellowish |
| 0.58 μm | Light orange |
| 0.60 μm | Carnation pink |
| 0.63 μm | Violet-red |
| 0.68 μm | Bluish |
| 0.72 μm | Blue-green to green |
| 0.77 μm | Yellowish |
| 0.80 μm | Orange |
| 0.82 μm | Salmon |
| 0.85 μm | Dull light red-violet |
| 0.86 μm | Violet |
| 0.87 μm | Blue-violet |
| 0.89 μm | Blue |
| 0.92 μm | Blue-green |
| 0.95 μm | Dull yellow-green |
| 0.97 μm | Yellow to yellowish |
| 0.99 μm | Orange |
| 1.00 μm | Carnation pink |

Table II shows as an example, specific colors and associated thicknesses for Si₃N₄.

TABLE II

| Thickness | Color |
|---|---|
| 0-20 nm | Silicon |
| 20-40 nm | Brown |
| 40-55 nm | Golden brown |
| 55-73 nm | Red |
| 73-77 nm | Deep blue |
| 77-93 nm | Blue |
| 93-100 nm | Pale blue |
| 100-110 nm | Very pale blue |
| 110-120 nm | Silicon |
| 120-130 nm | Light yellow |
| 130-150 nm | Yellow |
| 150-180 nm | Orange red |
| 180-190 nm | Red |
| 190-210 nm | Dark red |
| 210-230 nm | Blue |
| 230-250 nm | Blue-green |
| 250-280 nm | Light green |
| 280-300 nm | Orange yellow |
| 300-330 nm | Red |

According to aspects of the disclosed subject matter, there are certain fabrication techniques that can be used that can enhance performance and at the same time ease manufacturing processes and/or costs, e.g., improving the work flow, e.g., especially in regard to how the flex substrate is folded around the insert. Such a so-called wrap step can be important in the fabrication processes, e.g., since it can lay a foundation for good cosmetics and can also impact proper functionality, e.g., promoting a thinner button overall lamination. As an example, it may be important that the surface be relatively flat to achieve both of these. At least two general applications of the flex being assembled onto the insert include molding the sensor part of the flex substrate onto the insert as the insert is created. In such a case the flex top surface can be made flat due to the fact that the mold cavity that is provided can be made flat.

After molding these parts together the front edge and rear edges of the flex can then be wrapped around the insert and, e.g., secured with adhesive. The insert can be created using various forms of molding processes (the insert can also be formed, for example, by machining/cutting), such as, polycarbonate mold, epoxy mold, etc. In the second example, the insert can be molded (the insert can also be formed, for example, by machining/cutting) as a separate piece and then the flex substrate can be wrapped around the molded insert, e.g., using adhesive and/or mechanical means. In this case the flex sensor element traces should be aligned properly to the insert. This can be done, e.g., using alignment pins or holes on the insert either in the front part of the flex or in an alternate location. If dog ears are created on the flex then these can possibly be utilized as alignment structures, e.g., with the aid of a mechanical jig that can be utilized, e.g., to center and lower the flex substrate onto the insert. For both of these processes, after the insert is wrapped with the flex substrate, the combined assembly can be adhered into the button housing, which can then act as mechanical support and a bezel can then be added to the outer edge. The next assembly steps could then be to add a stiffener onto the housing and pot the full assembly, if desired. The top hard film could be laminated as a final assembly step or added to the insert before placing it into the housing.

The button assembly can thus be made in two separate molding or machining steps. In the first step the inner part of the button, i.e., including the insert, can be made and in the second step the finer detailed flanges and sidewalls, etc. of the button housing can be made. According to aspects of embodiments of the disclosed subject matter, the two step process could include, first, forming the insert, e.g., by molding, with or without the flex, then, if necessary wrapping the flex around the insert and then the insert piece with flex attached can be placed back into a mold or sequence of molds, whereby the flanges, sidewalls, bezel, etc. are made. In this manner the molding compound could, in some stage(s) act as the potting material as well. A hard film could also be created as part of the molding step or attached later as previously described.

Another method that could provide a lower cost manufacturing solution and add flexibility to the integration of the button into a user could provide the flex substrate with a tail on it designed to properly locate the button in the user device. This tail in some cases might be relatively long and irregularly shaped. Such size and shape could limit the total volume of sensors that could be made from a section of flex substrate, e.g., coming off of a flex film reel, since it may take extra space on the flex substrate film reel. This may be alleviated by removing the tail portion of the flex from the COF portion, e.g., where the sensor controller IC is mounted. A standard area of attach can be made on the COF to which to attach the tail, and any customized design for the tail can be chosen. This can improve the manufacturing costs/volumes, e.g., because the metallization patterns on the tail do not require the fine line widths that are required on the sensor element portion of the substrate and thicker polyimide substrates can also be used in the area of such a tail. Such a customized tail can then have the COF IC mounted on it, e.g., using anisotropic conductive film (ACF) attachment or the like.

Different methods may be utilized to, e.g., apply a hard coat on the button. Coating on film by roll-to-roll processing, whereby, e.g., color ink may be printed, using a gravure, slit, roller, or spray coating technique(s), on one side of a high K film and a hard coat applied on the other side of the flex substrate film. The printing process can proceed roll-to-roll. After coating is completed, the roll can, e.g., go through die cutting to create button covers. It is also possible to have both color coating and hard coat on the same side when needed. For coating directly on flex, the color ink and hard coat can be applied to the top of the sensor element flex substrate after the button is essentially completely assembled. The full stack can be applied as the final steps in the button construction.

Sputter deposited dielectric film can be utilized with resultant color effect: Oxide or nitride, e.g., SiO₂ or Si₃N₄ can be deposited at a selected thickness to create holographic-like color effect on the sensor flex substrate or high K films, as noted with respect to Tables I and II. At different viewing angles, such a layer can actually show a variety of colors. One or more such layers can also be deposited directly on a film or on top of matte colors, and after a dielectric film is formed. Hard coat can be applied to protect the dielectric film. A reduction in the layer thickness on top of the sensor to enhance the signal strength can be achieved.

According to aspects of embodiments of the disclosed subject matter an ultrathin button can be fabricated with a thickness of from about 0.2 mm to 1.2 mm. This can readily be increased to up to about 5 mm, if necessary, with a stiffer button. Such a design can, e.g., have the IC outside of button. The sensor controller IC is in the neighborhood, currently, of about 75 μm-400 μm. A less thin, but still quite compact button, having a thickness of about 1 mm-5 mm, can be made having, e.g., a length of around 6 mm-25 mm and a width of around 3 mm-25 mm, with a sensor controller IC having a thickness of around 75 μm to 600 μm. A radius of the flex substrate, which may be determined by the height of the insert may be dictated by the degree to which the metal traces on the flex can be bent without breaking, may be up to about one half the height (thickness) of the insert, i.e., about 50 μm to 500 μm. The thickness of the flex substrate may be around 12.5 μm to 75 μm, and the stiffener around 50 μm to 400 μm, and the bezel from around 0.3 mm to around 2 mm. The hump (mandrel) radius may be from about 0.5 mm to about 50 mm. The thickness of the hard film may be from about 25 μm to about 400 μm.

According to further aspects of the disclosed subject matter, suitable materials for use in fabricating the button(s) disclosed may consist of potential coatings such as, PED with or without filler; PVDF (Teflon®) with or without filler; glass, sapphire; polyimide, PVF (Dupont+Tedlar); organics or inorganics, and oxides or nitrides. Adhesives may include, e.g., for forming the flex substrate/insert assembly, pressure sensitive adhesive (PSA) (transfer film types and tape types), such as 3M PSA/OCA types: 200MP types, 8171, 8172, 467MP(F), 9461P, 8211, Adhesive Research PSA/OCA types EL925224, EL92524-99, Nitto Denko PSA/OCA types 5601, 5600 or liquid types, such as UV pre-activation types, ultraviolet (UV)/visible light curable: (DELO: 45952, 4552, GB345, Henkel: 4307, 3106, 3942, 3974, 5056); thermal cure types: (DELO: AD465, Dymax 9001-E-V3.0, Henkel), UV activated PSA types: (3M SP-7555); hot dispense types: Henkel; humidity types (Cyanoacrylate): Henkel 4307, 4306, 4310, DELO; Two and One part epoxies (DELO AD066); dry film types; thermal forming/hot melt: (PolyOne 55000, Adhesive Research EL770039-6); thermal plastic (DuPont 5400) and thermal set (ethylene-vinyl acetate (EVA)), etc. Other adhesives, e.g., for attaching the insert flex sub-assembly to the housing may include PSA —transfer film types and Tape types, e.g., 3M SP-7555,200MP types, 8171, 8172, 467MP(F), 9461P, 8211, Adhesive Research PSA/OCA types EL925224, EL92524-99, Nitto Denko PSA/OCA types 5601, 5600 or liquid types, e.g., UV pre-activation types: DELO: 45952, 4552, Henkel types; thermal cure types: DELO: AD465, AD066, Dymax:9001-E-V3.0; UV activated PSA types: (3M SP-7555); Hot dispense types: Henkel; humidity types (Cyanoacrylate): Henkel 4307, 4306, 4310, DELO or two and one part epoxies. Other adhesives, e.g., for attaching the housing and stiffener, may include, e.g., PSA—transfer film types and tape types, e.g., 3M SP-7555,200MP types, 8171, 8172, 467MP(F), 9461P, 8211, Adhesive Research PSA/OCA types EL925224, EL92524-99, Nitto Denko PSA/OCA types 5601, 5600 or liquid types, e.g., UV pre-activation types: DELO: 45952, 4552, Henkel types; thermal cure types: DELO: AD465, AD066, Dymax:9001-E-V3.0; UV activated PSA types: (3M SP-7555); hot dispense types: Henkel; humidity types (Cyanoacrylate): Henkel 4307, 4306, 4310, DELO and two and one part epoxies. Adhesives for attaching, e.g., a hard top film to the housing and stiffener sub-assembly may include, e.g., PSA—transfer film types and tape types, e.g., 3M PSA/OCA types:200MP types, 8171, 8172, 467MP(F), 9461P, 8211, Adhesive Research PSA/OCA types EL925224, EL92524-99, Nitto Denko PSA/OCA types 5601, 5600, liquid types, e.g., UV pre-activation types, UV/visible light curable: DELO: 45952, 4552, GB345, Henkel: 4307, 3106, 3942, 3974, 5056; thermal cure types: (DELO: AD465, Dymax 9001-E-V3.0, Henkel; UV activated PSA types: (3M SP-7555); hot dispense types: Henkel; humidity types (Cyanoacrylate): Henkel 4307, 4306, 4310, DELO and two and one part epoxies (DELO AD066) or dry film types, e.g., thermal forming/Hot Melt: (PolyOne 55000, Adhesive Research EL770039-6); thermal plastic (DuPont 5400) or thermal set (EVA). Adhesives for potting the button assembly may include, e.g., liquid types, e.g., thermal cure types: DELO: AD465, Dymax 9001-E-V3.0, Henkel; two and one part epoxies (3M DP270, DELO AD066, AD894, AD821) or RTV Silicones (Henkel 5040).

According to aspects of embodiments of the disclosed subject matter, a biometric sensor button assembly may include a top coating. This may be sprayed or printed, e.g., with various materials to meet reliability and cosmetic requirements directly onto the insert/flex or onto a hard film that already is or will be laminated to the insert/flex. The corners of the insert may be shaped, e.g., so that they maintain flatness out to the edges of the sensor/button assembly. That is, the corners may be shaped to be flat on top to support a top film at the edges of the four corners or the insert. In addition, in order to accommodate a deposited top film coating the corners of the insert should be rounded. In this manner the relatively compact sensor/button assembly can accommodate the deposited coatings, which may also be utilized to hide the interface on the middle insert between the flex substrate and the hard plastic of the insert.

Alternatively, the flex can be cut to include wings/dog ears as previously described. If not, a gap between these should be kept below about 20-100 μm in width and 10-50 μm in depth, e.g., to accommodate spray deposited top coating. This can be filled so that it looks flat after coating, e.g., by tuning the coating process, e.g., with proper pressure/deposition rate/temperature, or by applying a smoothing layer prior to the coating application. The smoothing layer might be first applied thickly and then smoothed/ground to be more flat. Or, the smoothing layer may have smoothing properties of its own during deposition/drying. Or the smoothing layer might be smoothed before drying/curing, e.g., by a squeegee/block coating technique. In such ways a compact biometric sensor/button assembly may be able to accommodate deposited coating layers in addition to a hard top film and be able to accommodate rectangular or round shaped sides.

It will be understood that there can be at least two general cases for the top surface of the sensor/button assembly. A hard film can be laminated to the flex/insert assembly. This may have pigment already in it or it may require a deposited coating to achieve the right color. This color coating may be on the top or the bottom of the hard film, e.g., if the hard film is transparent and color is important to be different from the natural color of the hard film. It may also be necessary to add an additional deposited hard coat layer on top, e.g., to achieve scratch resistant, and, further possibly another anti-fingerprint layer on top of that. As another example, a top coating that is directly coating onto the flex/insert assembly, as opposed to being applied to a hard film, can be utilized. This could essentially involve applying the above mentioned layers (color, hard coat, anti-fingerprint) directly onto the flex/insert assembly. However, using the second choice with a purely coated top film could be more sensitive to surface roughness compared to a “rigid” hard film that has already (or will be) coated with the appropriate material. The hard film can hide some of the surface imperfections since it is semi-rigid.

Turning now to FIGS. 1-7 there is illustrated, by way of example, respectively, a top plan view, a top perspective view, a bottom perspective view, a left side view, an exploded view, and several cross-sectional views of a compact and durable button 10 with a biometric sensor having improved sensor signal production according to aspects of embodiments of the disclosed subject matter. The button 10 with integrated biometric sensor can have a button housing 12 with at least one side wall. The button 10 may be formed with a front side wall 16, a rear side wall 18 and a pair of longitudinal sidewalls 20. A bezel 22 may be formed at the interior edge of the side walls 16, 18 and 20, e.g., to assist in holding, as an example a top protective laminate 40 in place, where side walls are identified as, for example front and rear to provide orientation. The intersections of the front side wall 16 and the longitudinal side walls 20 and the rear side wall 18 and the longitudinal side walls 20 may form rounded corners 24.

As seen in more detail in the cross-sectional views of FIGS. 6-8, the side walls 16, 18 and 20 can form vertical support towers 26 extending upwards from the base 30 and acting to absorb vertically applied loads applied to the top of the button housing 12. The base 30 can form a flange 32 that can be utilized to assist in the housing functioning as a button, e.g., serving to retain the button housing 12, and thus the button 10, within, e.g., an opening within a chassis of a user device (not shown) wherein the button 10 button housing 12 moving up and down with respect to the opening in the chassis forms an operating mechanism for a physical button or switch assembly (not shown) also mounted with the chassis of the user device, when the button housing 12 moves up and/or down.

As will be explained in more detail below, a top protective laminate 40 can serve to protect structures, such as biometric sensor element traces mounted on, e.g., a flexible substrate 50, forming part of the biometric, e.g., fingerprint, sensor, i.e., the sensor element conductive metal traces 44, as are well known in the art. A slot 42 may be formed in the top protective laminate 40 to facilitate interaction between the user biometric, i.e., finger, and the sensor element(s) 44 under the top protective laminate 40. A top adhesive laminate 46, seen, e.g., in more clearly in the exploded view of FIG. 5 can serve to, at least in part, attach the top protective laminate 40 to a region of the flex substrate 50 in the area at the top of the button/sensor assembly 10, where the sensor elements 44 are located and where sensing of the user biometric, e.g., fingerprint occurs when, e.g., the user operates the button and thus places or at least swipes the finger over the sensing area of the sensor element metal traces 44 in doing so.

As seen in FIG. 5, a stiffener 60, such as a metal stiffener, may form a relatively rigid, but at least somewhat bendable, bottom support for the button housing 12 and its contents, as explained in more detail below. Alignment holes 62 may be present in the stiffener, e.g., to position the button/sensor assembly within a switch or button assembly, e.g., in the chassis of the user device, for operation as a button mechanism, e.g., for a switch (not shown). An adhesive stiffener 64 can be utilized to attach the stiffener 60 to the button housing 12 bottom and then, e.g., cured to harden the adhesive to attach the stiffener 60 and form a functional part of the stiffener 60, adding strength while providing at least some flexibility. An IC opening 66 allows the IC to project at least through the adhesive stiffener 64 toward the stiffener 60.

Turning to FIGS. 6-8 there are illustrated, respectively, two different lateral cross-sectional views and a longitudinal cross-sectional view of the button and biometric sensor assembly of FIGS. 1-5. In FIGS. 6 and 8 can be seen a sensor controller integrated circuit (“IC”) 54 housed within a cavity 114 formed within the interior of the structure of the button housing 12, also showing under fill 56, e.g., formed when the IC 54 was mounted to the flex substrate 50, e.g., in a chip on flex (“COF”) mounting process as is well known in the art.

Also shown is an insert 70 than fits within at least part of the interior of the button housing 12. An adhesive insert 72 can be wrapped around the insert 70 to facilitate placing and holding the insert 70 within the interior of the button housing 12. The insert 70 may have rounded corners 74 to receive the flexible substrate film 50 with limited damage when the flex substrate 50 is also wrapped about the insert 70. As seen in more detail in the exploded view of FIG. 5, the interior of the button housing 12 can also have a floor 80, part of which may be cut away to form ledges 82, or shelves, upon which may be formed strengthening ribs 84 to receive the entire insert assembly 90, i.e., the insert 70 and surrounding an adhesive insert 72 and flexible circuit substrate 50 film.

The exemplary cross-sectional view of FIG. 6 is taken in an area where the IC 54 is mounted on the flex substrate 50 and is received within a cavity 114, such as a first cavity formed within the insert 70. As can be seen in FIG. 6, the sensor element electrode metal traces can be formed on the bottom side of the flex substrate 50 where the flex substrate passes over the insert 70 at the top of the button, as shown in FIG. 6, which then is on the top side of the flex substrate 50 within the cavity 114, where the IC 54 is mounted, e.g., as a COF, with under fill 56. Applicants have denominated this arrangement as “copper (Cu) down”, since copper is a suitable and preferable metal material for the sensor element electrode metal traces formed on the flex substrate 50. A suitable filler material, e.g., a potting material, such as epoxy, or the like, may be placed in the cavity 114 during the manufacturing process to harden around the under fill 56 of the IC 54 to further protect the IC from vertical loading stress.

It can be seen with respect to FIG. 8 that the insert 70 can be supported against vertical movement or deflection by resting on ledges 82 at either end of the opening in the button housing 12. This, as well as the support from the stiffener 60 running under the button housing 12 makes the sensor/button assembly 10 relatively sturdy in the face of vertical loading on the top of the button/sensor assembly 10, thereby protecting the IC 54 in the cavity 114 from damage under such loading. It can also be seen in FIGS. 6-8 that the flexible substrate 50 can pass out of the button housing 12 through a slot formed in one of the longitudinal sidewalls 20 of the button housing 12. It will be understood that this slot could also be formed in one of the front side wall 16 and rear side wall 18.

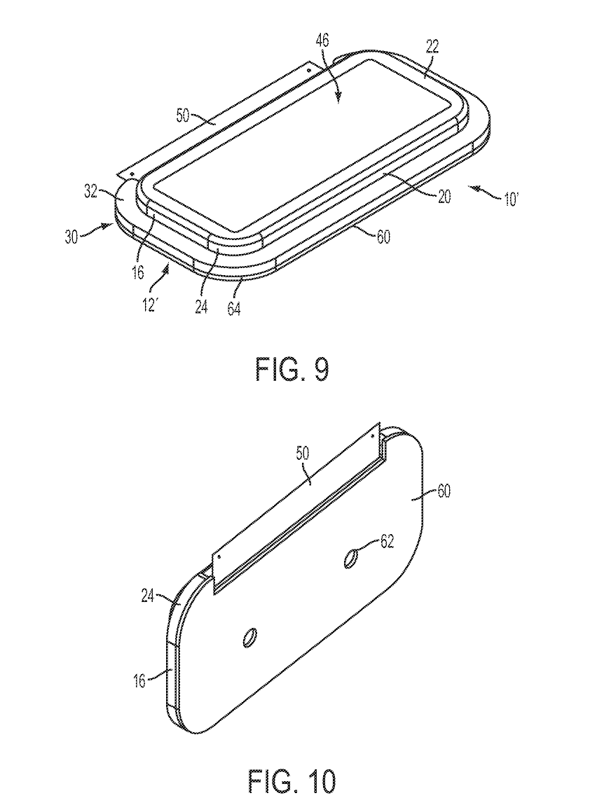

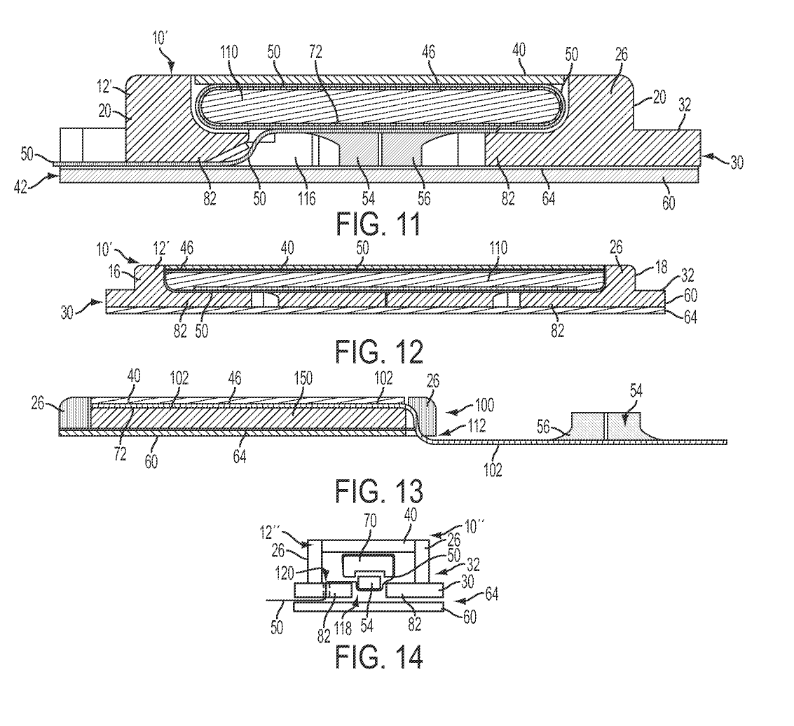

FIG. 9 illustrates a top perspective view and FIG. 10 illustrates a bottom perspective view of another compact and durable button 10′ with a biometric sensor having improved sensor signal production, according to aspects of embodiments of the disclosed subject matter. The sensor/button assembly 10′ has a modified button housing 12′, as explained in more detail with respect to FIGS. 11 and 12, showing, respectively, a lateral cross-sectional view and a longitudinal cross-sectional view of a so-called “copper (Cu) up” sensor element metal trace arrangement on the flex circuit of a flexible substrate 50. The sensor element electrode metal traces (not shown) can be formed on the top of the flex substrate 50 as it passed over the insert 110 such that the IC 54 can be mounted on the bottom side of the flex substrate 50 as it is passed through the cavity 116. The sensor element traces in this arrangement of FIGS. 8-11 may be coated with a protective coating, such as an ink, film or the like in the area of the relatively flat top protective laminate 40, which may be attached to the insert 110 and flexible substrate 50 by an adhesive layer 46. The flex substrate 50 may pass from the interior of the modified button housing 12′ through a slot 42.

As can be seen in more detail, in FIGS. 11 and 12, the insert 110 may be formed as a relatively flat-topped structure and rest upon or be supported by the ledges 82, thus being relatively sturdy against vertical loading to protect the IC 54 mounted on the flex substrate 50 on the bottom side of the flexible substrate 50 as it passed through a cavity 116 formed in the floor 80 of the modified button housing 12′. The cavity 116 in the floor 80 of the modified button housing 12′ may be formed with ledges 82 to support the insert/flex substrate assembly 110. The side walls 16, 18, 20 can be seen to be formed also with a relatively flat top, providing vertical loading strength to the button/sensor assembly 10′.

FIG. 13 illustrates a lateral cross-sectional view of another button 100, which is compact and durable, with a biometric sensor having improved sensor signal production and an ultra-low vertical profile according to aspects of embodiments of the disclosed subject matter. The sensor/button assembly may have an insert 150 that may be supported on the stiffener 60, or also with ledges (not shown) in the button housing 112. A relatively flat top protective laminate 40 may be attached to the flexible substrate 102, in either a “copper up” or “copper down” configuration with the flexible substrate passing from the housing and having the IC mounted to the flexible substrate 102 outside of the button housing 112, through an opening in the rear sidewall of the button 100.

FIG. 14 illustrates schematically, another possible sensor/button assembly 10″, with a cavity 118 formed partly within the bottom of the button housing 12″ and partly within the insert 70. The button housing 12,″ insert 70 and flex substrate 50 are arranged similarly to the less schematic view of FIGS. 9-12, except with a “copper down” flexible substrate arrangement as seen in more detail in FIGS. 1-8. However, as can be seen in schematic form in FIG. 14, the cavity 118 can be formed partly in the floor 80 of the interior of the button housing 12″ and partly within the insert 70. The insert 70 can be supported vertically by the ledges 82. The side wall vertical support towers 26 can also provide vertical loading structural support for the IC 54. It will be understood that the IC 54 may also be attached to the insert 70, e.g., by a suitable adhesive layer (not shown). Furthermore, the flexible substrate 50 may be attached to the portion of the cavity 118 within the insert 70 (as opposed to as is shown in FIG. 14), and the IC 54 then mounted on the opposite side of the flex circuit from that shown in FIG. 14, i.e., changing the flex substrate to a “copper up” arrangement. As before, suitable potting material may fill the cavity 118 to further protect the IC 54.

It will be understood that a biometric sensor and button combination assembly and method of making same is disclosed which may comprise: a button housing comprising at least two side walls each forming a vertical load absorbing tower and defining an opening within the button housing; an insert within the opening within the housing; a sensor controller integrated circuit positioned within a cavity formed in one of the insert, the housing or a combination of the insert and the housing; and the insert and the housing cooperating to absorb vertical loading on the button housing, thereby protecting the integrated circuit from excess vertical loading. The assembly and method may also comprise the biometric comprising a fingerprint sensed by the biometric sensor when a finger of a user presses on the top of the button to invoke the functionality of the button. The assembly and method may also comprise: the at least two side walls comprising at least four side walls, the cavity being formed within the bottom of the insert, spaced from the top of the button or within the housing under the bottom of the insert.

The assembly and method may further comprise the housing supporting the insert to prevent movement of the insert in a direction that would apply vertical loading applied to the button to the integrated circuit. The assembly and method may further comprise the insert being sized and constructed of material that prevents the insert from significantly bending in a direction that would apply to the integrated circuit any damaging amount of a vertical loading applied to the button. The assembly and method may further comprise the integrated circuit being mounted on a flexible substrate having sensor element traces formed on one surface of the substrate facing a top of the button on a top side of the insert and facing a bottom of the button on a bottom side of the insert or formed on one surface of the substrate facing a bottom of the button on a top side of the insert and facing a top of the button on a bottom side of the insert.

The assembly and method may further comprise the assembly being incorporated into a user authentication apparatus providing user authentication for controlling access to one of an electronic user device or an electronically provided service and the electronic user device comprises at least one of a portable phone, a computing device or the provided service comprises at least one of providing access to a web site or to an email account or controlling an online transaction or providing user authentication for controlling access to a physical location or demonstrating the user was present at a certain place at a certain time or for providing at least one of a finger motion user input or navigation input to a computing device or the performance by the user device of at least one other task specific to the particular finger of the user.

The assembly and method may further comprise a button housing comprising at least two side walls each forming a vertical load absorbing tower and defining an opening within the button housing; an insert within the opening within the housing; a flexible circuit substrate containing sensor element conductor traces formed over the insert, the insert and the vertical load absorbing towers cooperating to also absorb vertical loading on the button housing, thereby protecting the sensor conductor traces from damage due to excess vertical loading; and the flexible circuit substrate extending outside of the housing an having an integrated circuit mounted to the flexible circuit substrate outside of the housing of the button.

It will be understood by those skilled in the art that the disclosed subject matter provides a biometric authentication system wherein a biometric image sensor can be incorporated into a user authentication apparatus providing user authentication, e.g., for controlling access to one of an electronic user device or an electronically provided service. The electronic user device may comprise at least one of a portable phone and a computing device. The electronically provided service may comprise at least one of providing access to a web site or to an email account. The biometric image sensor may be incorporated into a user authentication apparatus providing user authentication for controlling an online transaction. The user authentication apparatus may be a replacement of at least one of a user password or personal identification number. The user authentication apparatus may be incorporated into an apparatus providing user authentication for controlling access to a physical location, or providing user authentication demonstrating the user was present at a certain place at a certain time. The user authentication apparatus may be incorporated into an apparatus providing at least one of a finger motion user input or navigation input to a computing device. The user authentication apparatus may be incorporated into an apparatus providing authentication of the user to a user device and the performance by the user device of at least one other task, e.g., specific to a particular finger of the user. The user authentication apparatus may be incorporated into an apparatus providing user authentication for purposes of making an online transaction non-repudiatable.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

What is claimed is:

1. A sensor and button apparatus, comprising:
a flexible substrate;
sensor elements disposed on the flexible substrate;
an integrated circuit (IC) disposed on the flexible substrate, the IC being communicatively coupled to the sensor elements;
an insert having a top side and a bottom side; and
a button housing having a top side, a bottom side, and at least one sidewall,
wherein the flexible substrate is wrapped around the insert with the sensor elements of the flexible substrate at the top side of the insert, and
wherein the insert is disposed within an interior of the button housing with the top side of the insert corresponding to the top side of the button housing.

2. The apparatus of claim 1, wherein the flexible substrate wrapped around the insert includes a portion extending outside of the button housing, and the IC is disposed on the portion of the flexible substrate extending outside of the button housing.

3. The apparatus of claim 2, wherein the at least one sidewall includes a slot, and wherein the portion of the flexible substrate extending outside of the button housing extends from the insert through the slot.

4. The apparatus of claim 1, wherein the flexible substrate is wrapped around the insert with the IC at the bottom side of the insert.

5. The apparatus of claim 4, wherein the insert includes a cavity, and wherein the IC is disposed within the cavity of the insert.

6. The apparatus of claim 5, wherein the IC is disposed facing up from the flexible substrate within the cavity of the insert.

7. The apparatus of claim 4, wherein the button housing defines a cavity, and wherein the IC is disposed within the cavity of the button housing.

8. The apparatus of claim 7, wherein the IC is disposed facing down from the flexible substrate within the cavity of the button housing.

9. The apparatus of claim 4, wherein the insert includes a first cavity, wherein the button housing defines a second cavity, and wherein the IC is disposed within the first cavity of the insert and the second cavity of the button housing.

10. The apparatus of claim 1, wherein the at least one side wall includes at least one ledge in the interior of the button housing, and wherein the insert with the flexible substrate wrapped around it is vertically supported by the ledge.

11. The apparatus of claim 1, further comprising:
a hard top film,
wherein the sensor elements are disposed facing up from the flexible substrate at the top side of the insert, and
wherein the hard top film coats the flexible substrate at the top side of the insert.

12. The apparatus of claim 1, further comprising:
a conformal coating,
wherein the sensor elements are disposed facing down from the flexible substrate at the top side of the insert, and
wherein the conformal coating coats the flexible substrate at the top side of the insert.

13. The apparatus of claim 1, wherein the sensor elements comprise a capacitive sensor array.

14. The apparatus of claim 1, wherein the sensor elements comprise a capacitive fingerprint sensor array.

15. The apparatus of claim 1, wherein the sensor elements comprise a swipe fingerprint sensor array.

16. The apparatus of claim 1, wherein the sensor elements comprise a placement fingerprint sensor array.

17. The apparatus of claim 1, wherein the button housing is user depressible from the top side of the button housing.

18. The apparatus of claim 17, further comprising:
a device housing,
wherein the button housing is disposed in the device housing and user depressible relative to the device housing.

19. A sensor and button apparatus, comprising:
a flexible substrate;
fingerprint sensor electrodes disposed on the flexible substrate;
an integrated circuit (IC) disposed on the flexible substrate, the IC being communicatively coupled to the sensor electrodes;
an insert having a top side and a bottom side; and
a button housing having a top side, a bottom side, and at least one sidewall, the button housing being user depressible from the top side of the button housing,
wherein the flexible substrate is wrapped around the insert with the sensor electrodes of the flexible substrate at the top side of the insert and the IC at the bottom side of the insert,
wherein the insert is disposed within an interior of the button housing with the top side of the insert corresponding to the top side of the button housing,
wherein the insert comprises a cavity at the bottom side of the insert,
wherein the IC is disposed facing up from the flexible substrate within the cavity of the insert.

20. A sensor and button apparatus, comprising:
a flexible substrate;
fingerprint sensor electrodes disposed on the flexible substrate;
an integrated circuit (IC) disposed on the flexible substrate, the IC being communicatively coupled to the sensor electrodes;
an insert having a top side and a bottom side; and
a button housing having a top side, a bottom side, and at least one sidewall, the button housing being user depressible from the top side of the button housing,
wherein the flexible substrate is wrapped around the insert with the sensor electrodes of the flexible substrate at the top side of the insert and the IC at the bottom side of the insert,
wherein the insert is disposed within an interior of the button housing with the top side of the insert corresponding to the top side of the button housing,
wherein the button housing defines a cavity at the bottom side of the button housing,
wherein the IC is disposed within the cavity of the button housing facing down from the flexible substrate and facing down from the insert.
